(19) United States
(12) Patent Application Publication
(10) Pub. No.: US 2015/0097254 A1
(43) Pub. Date: Apr. 9, 2015

(54) MEMORY ELEMENT, METHOD OF MANUFACTURING THE SAME, AND MEMORY DEVICE

(71) Applicant: Sony Corporation, Tokyo (JP)

(72) Inventors: Hiroyuki Ohmori, Kanagawa (JP); Masanori Hosomi, Tokyo (JP); Kazuhiro Bessho, Kanagawa (JP); Yutaka Higo, Kanagawa (JP); Kazutaka Yamane, Kanagawa (JP); Hiroyuki Uchida, Kanagawa (JP)

(21) Appl. No.: 14/476,970

(22) Filed: Sep. 4, 2014

(30) Foreign Application Priority Data
Oct. 9, 2013 (JP) 2013-212095

(51) Int. Cl. H01L 27/22; H01L 43/02; H01L 43/10; H01L 43/12

(52) U.S. Cl. CPC H01L 27/222; H01L 43/12; H01L 43/02; H01L 43/10
USPC 257/421; 438/3

(57) ABSTRACT

A memory element having a layer structure, the layer structure includes: a memory layer whose magnetization direction is changed in accordance with information; a magnetization-fixed layer having magnetization perpendicular to a film surface to be a basis of the information stored in the memory layer; and an intermediate layer made of a non-magnetic material, disposed between the memory layer and the magnetization-fixed layer, wherein at least a periphery of the memory layer is covered with a magnetic material through a non-magnetic material among the layer structure.

### CROSS REFERENCE TO RELATED APPLICATIONS

This application claims the benefit of Japanese Priority Patent Application JP 2013-212095 filed Oct. 9, 2013, the entire contents of which are incorporated herein by reference.

### BACKGROUND

The present disclosure relates to a memory element for recording information using spin torque magnetization reversal, a method of manufacturing the same, and a memory device.

With a tremendous development of various kinds of information apparatuses from large capacity servers to mobile terminals, further improvements in performance, such as higher integration, higher speed, lower power consumption, and the like have been pursued in elements, such as a memory, a logic, and the like that are included in the apparatuses. In particular, there has been a remarkable progress in semiconductor non-volatile memories. Flash memories have been widespread as mass storage file memories, and are in the process of replacing hard disk drives. On the other hand, in order to be put into practical use for code storage, and further, as a working memory, and to replace a NOR flash memory, a DRAM, and the like, which are currently used in general, a FeRAM (Ferroelectric Random Access Memory), a MRAM (Magnetic Random Access Memory), a PCRAM (Phase-Change Random Access Memory), and the like are currently being developed. Some of these have already been put to practical use.

Among these, the MRAM stores data by magnetization directions of a magnetic material so that it is possible to rewrite the MRAM at a high speed for substantially unlimited number of times (10¹⁵ times or more). The MRAM has already been put to use in fields, such as industrial automation, airplanes, and the like. The MRAM is expected for use in code storage and as a working memory in the future because of high-speed operation and reliability. However, in reality, the MRAM has challenges for lowering power consumption, and for increasing capacity. This is an intrinsic problem caused by the recording principle of the MRAM, that is to say, the method of reversing magnetization by a current magnetic field generated by wiring lines.

As one of the methods for solving this problem, a recording method that does not use a current magnetic field, that is to say, a magnetization reversal method is being studied. In particular, researches have actively been made on spin torque magnetization reversal (for example, refer to Japanese Unexamined Patent Application Publication Nos. 2003-17782 and 2008-227388, U.S. Pat. No. 6,256,223, Physical Review B, 54, 9353 (1996), Journal of Magnetism and Magnetic Materials, 159, L1 (1996), and Nature Materials., 5, 210 (2006)).

The memory element using spin torque magnetization reversal includes an MTJ (Magnetic Tunnel Junction) (TMR (Tunneling Magnetoresistive)) element.

This configuration uses a fact in which when spin polarized electrons passing through a magnetic layer that is fixed in a certain direction enter into an another free (the direction is not fixed) magnetic layer, a torque (this is also called as a spin injection torque) is applied to the magnetic layer, and the free magnetic layer is reversed when a current higher than a certain threshold value or more flows. The rewriting of 0/1 is performed by changing the polarity of the current.

In the case of a memory element having a scale of approximately 0.1 μm, the absolute value of a current for this reversal is 1 mA or less. Moreover, this current value decreases in proportion to the volume of the element, and thus scaling is possible. Furthermore, a word line for generating a recording current magnetic field is not necessary, and thus there is an advantage in that the cell structure becomes simple.

Hereinafter, the MRAM using the spin torque magnetization reversal is referred to as an ST-MRAM (Spin Torque-Magnetic Random Access Memory). The spin torque magnetization reversal is also referred to as a spin injection magnetization reversal. High expectations are placed on the ST-MRAM as a nonvolatile memory that enables lower power consumption, a larger capacity while keeping the advantages of the MRAM capable of rewriting at a high speed for substantially unlimited number of times.

### SUMMARY

Incidentally, if the memory elements (the ST-MRAM elements) are filled at a high density, each of the memory elements magnetically influences with one another, and retention characteristic and recording characteristic are influenced. In the MRAM element having in-plane magnetization, a proposal has been made of a method of reducing magnetic influences in the case of filling the memory elements (the ST-MRAM elements) at a high density by forming a low-retention force layer on the top of the magnetic material of the memory layer holding records to decrease the leakage magnetic field from the memory layer (refer to Japanese Unexamined Patent Application Publication (Translation of PCT Application) No. 2005-513795). However, in the case of the ST-MRAM element, it is not possible to reduce a leakage magnetic field by this method.

Thus, in the present disclosure, it is desirable to provide a memory element having stable retention characteristic and recording characteristic even if the memory elements are filled at a high density by reducing a leakage magnetic field that occurs from the memory element itself in order to decrease interaction among the memory elements.

According to an embodiment of the present disclosure, there is provided a memory element having a layer structure, the layer structure including: a memory layer whose magnetization direction is changed in accordance with information; a magnetization-fixed layer having magnetization perpendicular to a film surface to be a basis of the information stored in the memory layer; and an intermediate layer made of a non-magnetic material, disposed between the memory layer and the magnetization-fixed layer, wherein at least a periphery of the memory layer is covered with a magnetic material through a non-magnetic material among the layer structure.

In this manner, the periphery of the memory layer is covered with a magnetic material through a non-magnetic material, and thus a leakage magnetic field generated from the memory element itself is reduced.

In the memory element according to the present disclosure, the non-magnetic material is preferably an insulating material.

In this manner, the non-magnetic material is an insulating material, and thus stability increases when recording in the memory element.

In the memory element according to the present disclosure, the non-magnetic material preferably has a thickness of 0.5 nm to 5 nm, and the magnetic material preferably has a thickness of 0.5 nm to 5 nm.

In this manner, with the above-described thickness, stability increases when recording in the memory element.

The memory element according to the present disclosure preferably further includes a magnetic coupling layer being adjacent to the magnetization-fixed layer, and disposed on an opposite side of the intermediate layer.

In this manner, the magnetic coupling layer is disposed, and thus a leakage magnetic field generated from the memory element itself is reduced.

In the memory element according to the present disclosure, a vertical sectional shape of the layer structure in a lamination direction is preferably substantially a circle.

In this manner, it is preferable that the vertical sectional shape is substantially a circle, and thus the memory element is suitable for being filled at a high density.

According to another embodiment of the present disclosure, there is provided a method of manufacturing a memory element having a layer structure including a memory layer whose magnetization direction is changed in accordance with information, a magnetization-fixed layer having magnetization perpendicular to a film surface to be a basis of the information stored in the memory layer, and an intermediate layer made of non-magnetic material, disposed between the memory layer and the magnetization-fixed layer, the method including: laminating a foundation layer; laminating the memory layer, the magnetization-fixed layer, the intermediate layer; laminating a protection layer; and covering at least a periphery of the memory layer with a magnetic material through a non-magnetic material among the layer structure produced by each of the laminatings.

In this manner, the method includes covering with a magnetic material through a non-magnetic material in the lamination direction of the laminated element, and thus a leakage magnetic field generated from the memory element itself is reduced.

The method of manufacturing a memory element, according to the present disclosure may further include after laminating the foundation layer, the magnetization-fixed layer, the intermediate layer, the memory layer, and the protection layer, and covering at least the periphery of the memory layer with a magnetic material through a non-magnetic material among the laminated layer structure, filling with a filling material; and exposing an electrode portion from an upper part of the protection layer, wherein the covering with the magnetic material uses an anisotropic etching method having selectivity.

In this manner, an anisotropic etching method is used, and thus it is possible to reliably cover the periphery of the memory layer with a magnetic material.

According to another embodiment of the present disclosure, there is provided a memory device including a memory element holding information by a magnetization state of a magnetic material, and two kinds of wiring lines crossing with each other, all of or a part of the memory element having a layer structure, the layer structure including: a memory layer whose direction is changed in accordance with the information; a magnetization-fixed layer having magnetization perpendicular to a film surface to be a basis of the information stored in the memory layer; and an intermediate layer made of a non-magnetic material, disposed between the memory layer and the magnetization-fixed layer, wherein at least a periphery of the memory layer is covered with a magnetic material through a non-magnetic material among the layer structure, the magnetization direction of the magnetic layer is changed by applying a current in a lamination direction of the layer structure so that the information is recorded on the memory layer, and the current flows through the memory element in the lamination direction through the two kinds of wiring lines.

In this manner, the side face of the layer structure is covered with a magnetic material through a non-magnetic material, and thus it is possible to reduce a leakage magnetic field.

By the present disclosure, it is possible to reduce a magnetic field (leakage magnetic field) generated by the memory element (ST-MRAM element) itself, and thus it is possible to reduce the influence by magnetic fields between adjacent memory elements. Accordingly, it is possible to provide a memory device capable of filling memory elements at a high density, and having stable retention characteristic and recording characteristic.

In this regard, the advantages described here are not necessarily limited, and any one of the advantages in the present disclosure may be obtained.

### BRIEF DESCRIPTION OF THE DRAWINGS

FIG. 1 is a diagram illustrating a layer structure of a memory element to be a target of an embodiment;

FIGS. 2A and 2B are diagrams illustrating mutual interference by leakage magnetic fields of memory elements to be a target of the embodiment;

FIGS. 3A and 3B are diagrams illustrating a specific configuration of a memory element according to the embodiment;

FIGS. 4A, 4B, 4C, and 4D are examples of the other configurations of memory elements according to the embodiment;

FIGS. 5A, 5B, 5C, 5D, 5E, 5F, and 5G are diagrams illustrating a method of manufacturing a memory element according to the embodiment;

FIG. 6 is a diagram illustrating a configuration of a memory element used for an experiment;

FIG. 7 is a diagram illustrating an experiment result of a relationship between thickness of an insulating layer and stability index; and

FIG. 8 is a diagram illustrating an experiment result of a relationship between thickness of a soft magnetic layer and stability index.

### DETAILED DESCRIPTION OF EMBODIMENTS

In the following, a description will be given of embodiments according to the present disclosure in the following order.

1. Overview of memory element to be a target of an embodiment

2. Mutual magnetic interference of memory element to be a target of an embodiment

3. Specific configuration of memory element according to an embodiment

4. Method of manufacturing memory element according to an embodiment

5. Experiment

1. Overview of Memory Element to be a Target of an Embodiment

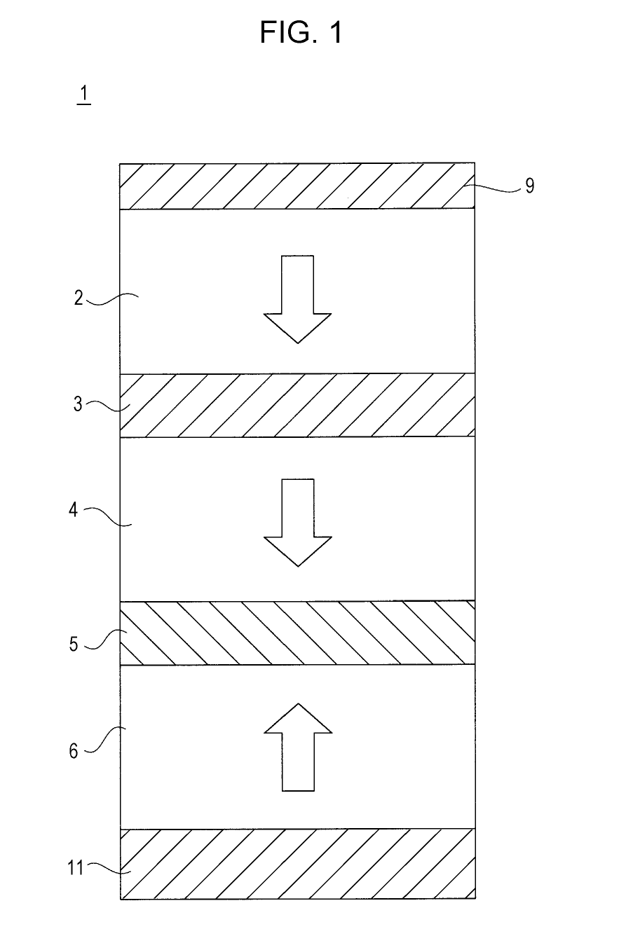

A description will be given of an overview of a memory element to be a target of an embodiment of the present disclosure with reference to FIG. 1.

A memory element 1 to be a target of an embodiment of the present disclosure records information by reversing the magnetization direction of a memory layer 2 of the memory element 1 by the spin torque magnetization reversal described above.

FIG. 1 is a diagram illustrating a preferable example of a basic layer structure of the memory element 1 to be a target of an embodiment. As illustrated in FIG. 1, the memory element 1 to be a target includes a foundation layer 11, a magnetic coupling layer 6, a bonding layer 5, a magnetization-fixed layer 4, an intermediate layer 3, a memory layer 2, and a protection layer 9.

The memory layer 2 is formed by a magnetic material including a ferromagnetic layer, and holds information by a magnetization state (magnetization direction) of the magnetic material.

The magnetization-fixed layer 4 is a layer that is magnetized fixedly in a certain direction, and becomes a basis of the information. The intermediate layer 3 is a so-called tunnel barrier layer, and is laminated between the memory layer 2 and the magnetization-fixed layer 4. In general, it is possible to configure an MTJ (Magnetic Tunnel Junction) element by the memory layer 2, the intermediate layer 3, and the magnetization-fixed layer 4.

The magnetic coupling layer 6 and the magnetization-fixed layer 4 are laminated in order to improve performance as the memory element 1.

That is to say, the magnetic coupling layer 6 is magnetically coupled to the magnetization-fixed layer 4 so that leakage magnetic fields from the magnetization-fixed layer 4 and the magnetic coupling layer 6 are canceled with each other. Thereby, the magnetic influence on the memory layer 2 preferably becomes small. Also, the bonding layer 5 magnetically couples the magnetization-fixed layer 4, and the magnetic coupling layer 6 further stronger.

The protection layer 9 and the foundation layer 11 are used for electrodes, and the like.

The memory layer 2, the magnetization-fixed layer 4, and the magnetic coupling layer 6 are formed by a magnetic material. This magnetic material is a magnetic material having a certain degree of coercive force, and is desirable to be an amorphous perpendicular magnetization film, such as TbFeCo, GdFeCo, or the like, a magnetic film having magneto crystalline anisotropy, such as CoPt, FePt, or the like, a laminated film of Co/Pt or Co/Pd, or a material using interface anisotropy between an oxide and a magnetic material.

The intermediate layer 3 is a tunnel barrier film, and has a tunnel resistance that is changed depending on the magnetization direction between the memory layer 2 and the magnetization-fixed layer 4, and allows reading information. Also, when recording by spin injection magnetization reversal, it is possible to perform magnetization reversal of the memory layer 2 by flowing a spin current between the memory layer 2 and the magnetization-fixed layer 4 through the intermediate layer (the tunnel barrier layer) 3.

For the intermediate layer 3, a material having a high magneto-resistance change rate (MR ratio) in order to read a magnetization state is preferable. For example, an oxide, such as MgO, Al₂O₃, or the like is suitable.

The bonding layer 5 is a non-magnetic layer, and magnetic interaction between the magnetization-fixed layer 4 and the magnetic coupling layer 6 is strengthened.

The magnetic interaction is preferable to be as strong as possible such that the magnetization-fixed layer 4 and the magnetic coupling layer 6 are coupled in an anti-parallel state. For example, it is desirable to use a metal non-magnetic material, such as Cr, Cu, Ru, Re, Os or the like.

Here, a description has been given of the configuration in which the memory layer 2 is disposed at the upper side, and the magnetization-fixed layer 4 is disposed at the lower side. However, the memory layer 2 may be disposed at the lower side, and the magnetization-fixed layer 4 may be disposed at the upper side. Also, two magnetization-fixed layers 4 may be disposed both at the upper side and the lower side of the memory layer 2, respectively.

Also, the memory element 1 illustrated in FIG. 1, that is to say, the memory element 1 including the lamination of the magnetization-fixed layer 4 and the magnetic coupling layer 6, which are magnetically coupled, is targeted as a preferable embodiment. However, a lamination of only the magnetization-fixed layers 4 having a large coercive force may be targeted as an embodiment.

Here, a brief description will be given of spin torque magnetization reversal by taking the MTJ element, in which the magnetization-fixed layer 4, the memory layer 2, and the intermediate layer 3 are laminated, as an example.

Electrons have two kinds of spin angular momentum. The two kinds of the momentum are tentatively defined as upward, and downward, respectively. Both of them are equal in number inside a non-magnetic material, but there is a difference in number inside a ferromagnetic material. In the magnetization-fixed layer 4 and the memory layer 2, which are two layers of ferromagnetic materials that constitute the ST-MRAM (the MTJ element), the following consideration is given to the case where when the magnetic moment directions of both of them are opposite to each other, and electrons are moved from the magnetization-fixed layer 4 to the memory layer 2.

The magnetization-fixed layer 4 has a high coercive force, and thus is a fixed magnetic layer in which the magnetic moment direction is fixed.

The electrons that have passed the magnetization-fixed layer 4 are subjected to spin polarization, that is to say, have a difference in number between the upward direction and the downward direction. If the intermediate layer 3, which is a non-magnetic layer, is configured to be sufficiently thin, spin polarization is alleviated by the passage through the magnetization-fixed layer 4, and thus electrons reach the magnetic material, that is to say, the memory layer 2 before going into an unpolarized (the same number between upward and downward) state in a normal non-magnetic material.

In the memory layer 2, the signs of the spin polarization degree are opposite, and thus some of the electrons are reversed in order to decrease energy in the system, that is to say, the direction of the spin angular momentum is changed. At this time, the total angular momentum of the system has to be conserved, and thus the counteraction that is equivalent to the total change in spin angular momentum, caused by the electrons having changed directions, is given to the magnetic moment of the memory layer 2. If a current, that is to say, the number of electrons passing per unit time, is low, the total number of electrons changing the directions is small, and thus there is a small change in spin angular momentum that occurs in the magnetic moment of the memory layer 2. However, when the current increases, it is possible to give a large change in spin angular momentum per unit time.

A change of angular momentum in time is a torque. If the torque exceeds a certain threshold value, the magnetic moment of the memory layer 2 causes to start precession, and the magnetic moment becomes stable at the point after rotation of 180 degrees because of its uniaxial anisotropy. That is to say, a reversal occurs from the reverse direction state to the same direction state.

When the magnetization is in the same direction, if the current flows reversely, that is to say, in the direction in which electrons are sent from the memory layer 2 to the magnetization-fixed layer 4, a torque is given at the time of being reflected by the magnetization-fixed layer 4 when spin reversed electrons enter into the memory layer 2. Thus, it is possible to reverse the magnetic moment to the reverse direction state. However, at this time, the amount of current that is necessary for causing the reversal becomes higher than in the case of reversing the magnetic moment from the reverse direction state to the same direction state.

It is difficult to intuitively understand the reversal of magnetic moment from the same direction state to the reverse direction state. However, it may be thought that the magnetization-fixed layer 4 is fixed so that the magnetic moment is difficult to be reversed, and thus the memory layer 2 is reversed in order to conserve the angular momentum of the overall system. In this manner, the recording of 0/1 is carried out by flowing a current higher than a certain threshold value corresponding to each of the polarities in the direction from the magnetization-fixed layer 4 to the memory layer 2, or in the reverse direction thereto.

Reading information is performed using magneto resistance effects in the same manner as in the case of a general MRAM. That is to say, a current is applied to flow in the perpendicular direction of the film face in the same manner as the case of the recording described above. Then, a phenomenon is used in which an electric resistance of the element is changed in accordance with whether the magnetic moment of the memory layer 2 has the same direction or the reverse direction with respect to the magnetic moment of the magnetization-fixed layer 4.

The material to be used as the intermediate layer 3 between the magnetization-fixed layer 4 and the memory layer 2 may be a metal or an insulating material. However, in the case of using an insulating material as the intermediate layer 3, a higher reading signal (the rate of change in resistance) is obtained, and the recording is possible using a lower current. The element at this time is referred to as a magnetic tunnel junction (MTJ).

The threshold value Ic of the current necessary when the magnetization direction of the magnetic layer is reversed by spin torque magnetization reversal is different depending on whether the axis of easy magnetization of the magnetic layer is the in-plane direction, or the perpendicular direction.

The memory element according to the present embodiment is based on perpendicular magnetization. However, it is assumed that a reversal current that reverses the magnetization direction of the magnetic layer in the case of a memory element based on related-art in-plane magnetization is Ic_para. In the case of reversing from the same direction to the reverse direction,

Ic_para=(A·α·Ms·V/g(0)/P)(Hk+2πMs).

In the case of reversing from the reverse direction to the same direction,

Ic_para=−(A·α·Ms·V/g(π)/P)(Hk+2πMs).

In this regard, the same direction and the reverse direction are magnetization directions of the memory layer 2 that are viewed on the basis of the magnetization direction of the magnetization-fixed layer 4. They are referred to as a parallel, and anti-parallel, respectively.

On the other hand, it is assumed that the reversal current of the memory element based on perpendicular magnetization as in the case of the present embodiment is Ic_perp. In the case of reversing from the same direction to the reverse direction,

Ic_perp=(A·α·Ms·V/g(0)/P)(Hk−4πMs).

In the case of reversing from the reverse direction to the same direction,

Ic_perp=−(A·α·Ms·V/g(π)/P)(Hk−4πMs).

Note that A is a fixed number, α is a damping constant, Ms is saturation magnetization, V is an element volume, P is a spin polarization rate, g(0) and g(π) are coefficients corresponding to efficiencies of transferring spin torque to the opponent magnetic layer at the time of the same direction, and the reverse direction, respectively, and Hk is magneto anisotropy.

In each of the above-described expressions, when a comparison is made between (Hk−4πMs) in the case of the perpendicular magnetization, and (Hk+2πMs) in the case of the in-plane magnetization, it is possible to understand that the perpendicular magnetization is suitable for lower memory current.

Here, the reversal current Ic is expressed in terms of a relationship with a thermal stability index A as the following Expression 1.

$${I}_{C} = ( \frac{4 {ek}_{B} T}{\overline{h}} ) ( \frac{α Δ}{η} ) \qquad Expression 1$$

Note that e is an electric charge of an electron, η is a spin injection efficiency, overlined h is the reduced Plank constant, α is a damping constant, k_{B} is the Boltzmann constant, and T is temperature.

In the present embodiment, the memory element is configured to include the magnetic layer (memory layer 2) capable of holding information by a magnetization state, and the magnetization-fixed layer 4 having a fixed magnetization direction.

As an existent memory, it is necessary to hold written information. As an index of information holding ability, a determination is made by a value of a thermal stability index Δ (=KV/k_{B}T). The Δ value is expressed by the following Expression 2.

$$Δ = \frac{KV}{{k}_{B} T} = \frac{{M}_{s} {VH}_{k}}{2 {k}_{B} T} \qquad Expression 2$$

Here, Hk is an effective anisotropy magnetic field, k_{B} is the Boltzmann constant, T is temperature, Ms is the amount of saturation magnetization, V is a volume of the memory layer 2, and K is anisotropy energy.

The effective anisotropy magnetic field Hk has imported the influences of shape magnetic anisotropy, induced magnetic anisotropy, magneto crystalline anisotropy, and the like. If an assumption is made of a simultaneous rotation model of a single magnetic domain, the effective anisotropy magnetic field Hk becomes equal to the coercive force.

The thermal stability index Δ and the threshold value Ic of the current often have a trade-off relationship. Accordingly, in order to maintain a memory characteristic, the challenges are often to have both of these.

The threshold value of the current that changes the magnetization state of the memory layer 2 is actually about a hundred to hundreds μA in the case of a circular element having the memory layer 2 with a thickness of 2 nm and having a plane pattern with a diameter of 100 nm, for example.

On the other hand, in an MRAM, in which magnetization reversal is performed by the current magnetic field, it is necessary to have a write current of a few mA or more.

Accordingly, in the case of the ST-MRAM, the threshold value of the write current becomes sufficiently small as described above, and thus it is understood that the power consumption of the integrated circuit is effectively reduced.

Also, it becomes unnecessary to dispose a wiring line for generating a current magnetic field, which is necessary for a normal MRAM, and thus it is more advantageous in terms of integration compared with a normal MRAM.

Then, in the case of performing spin torque magnetization reversal, a current is directly applied to the memory element to write (record) information. Accordingly, in order to select a memory cell to which information is written, a memory cell is configured by connecting the memory element with a selection transistor.

In this case, the current that flows to the memory element is restricted by a current that is allowed to flow through the selection transistor (the saturation current of the selection transistor).

In order to reduce the recording current, it is desirable to employ perpendicular magnetization as described above. Also, it is generally possible for a perpendicular magnetization film to have higher magneto anisotropy than in the case of an in-plane magnetization film, and thus it is desirable in view of keeping the above-described Δ value high.

2. Mutual Magnetic Interference of Memory Element to be a Target of an Embodiment

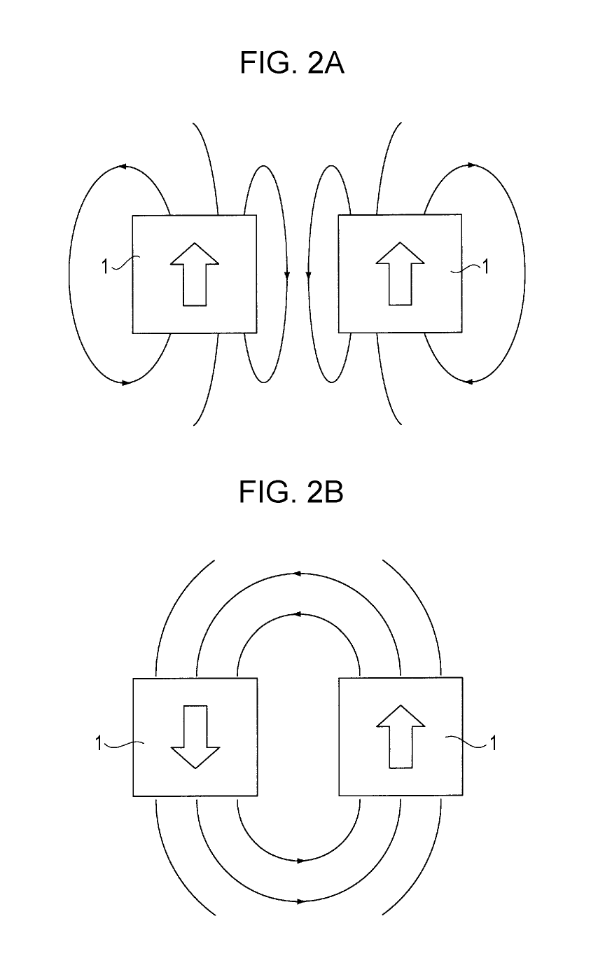

In the following, a description will be given of mutual interference of each magnetic field of adjacent memory elements 1 with reference to FIGS. 2A and 2B.

FIG. 2A is the case where the magnetization directions of the two memory elements 1 are parallel with each other. In this case, the magnetic fields generated by the memory elements 1 repel each other, and thus weaken magnetization, which is the contents of the recorded information, and thus the holding state the information (the magnetization direction) recorded in the memory element 1 becomes unstable. That is to say, it is thought that the recording state of the memory element 1 becomes unstable.

FIG. 2B is the case where directions of the magnetic fields are anti-parallel with each other. In this case, the memory elements 1 pull each other so that the magnetization is strengthened, and thus it is thought that the magnetization state, which is the contents of the recorded information, becomes stable. However, in order to record new information, it becomes necessary to apply a high current, and the power consumption inconveniently increases.

Here, it is thought that a leakage magnetic field generated from the memory element 1 is also generated from the memory layer 2. In the case of the memory element 1 illustrated in FIG. 1, the magnetization-fixed layer 4 and the magnetic coupling layer 6 are magnetically coupled, and thus the magnetic field generated from the magnetization-fixed layer 4 or the magnetic coupling layer 6 does not become a leakage magnetic field generated from the memory element 1. Accordingly, it is thought that the magnetic field generated from the memory layer 2 becomes the magnetic field generated from the memory element 1.

Also, in the case of an element without the magnetic coupling layer 6, that is to say, in the case of an element including the memory layer 2, the intermediate layer 3 and the magnetization-fixed layer 4, it is thought that only the magnetic field generated from the memory layer 2 ought to be considered as a leakage magnetic field.

It is apparent that when the density of a large number of memory elements 1 is increased, there are a stable memory element and an unstable memory element depending on the recording state (the state of the memory layer 2) of the memory element 1 for each memory element 1.

However, it is necessary to have both the retention characteristic that allows stable retention and the recording characteristic that allows recording in whichever recording state. Accordingly, in a high-density memory device or in order to increase the density of a memory device, it is important to suppress the magnetic interference between the memory elements.

3. Specific Configuration of Memory Element According to an Embodiment

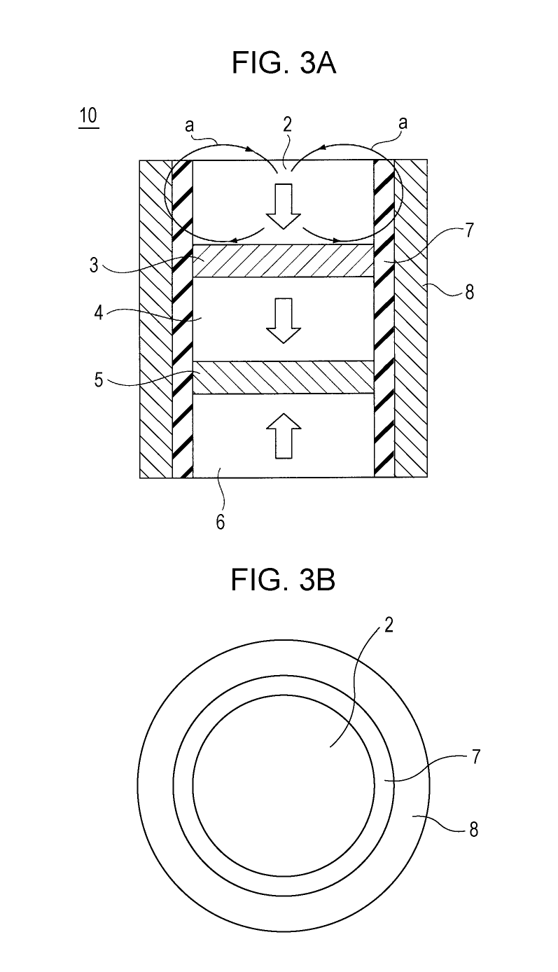

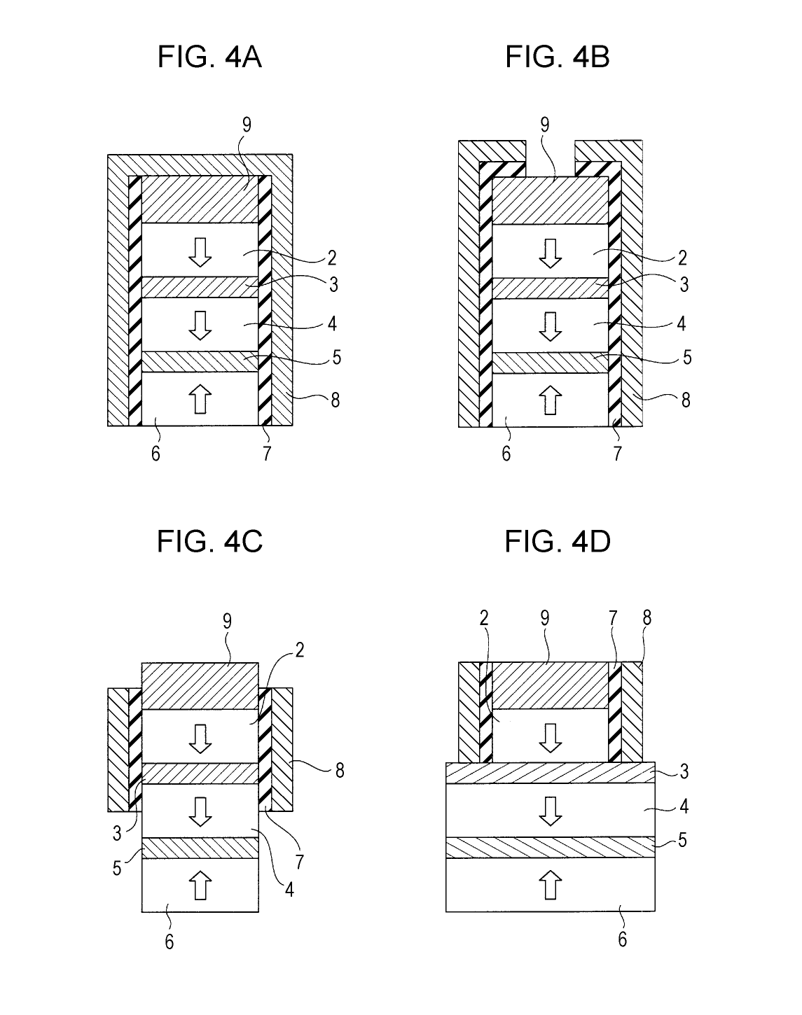

In the following, a description will be given of a specific configuration of a memory element according to the present embodiment with reference to FIGS. 3A, 3B, 4A, 4B, 4C, and 4D.

FIG. 3A is a sectional view of a memory element 10 according to the embodiment, and FIG. 3B is a top view of the memory element 10. In FIGS. 3A and 3B, the protection layer 1 and the foundation layer 11 are omitted. As illustrated in FIGS. 3A and 3B, in the memory element 10 according to the present embodiment, the periphery (side face) of the memory element 1 is covered with a non-magnetic material 7, and further, the outside thereof is covered with a soft magnetic material 8. These are formed in a cylindrical shape.

In FIGS. 3A and 3B, the overall periphery of the memory element 1 is covered. However, it is necessary that at least the periphery of the memory layer 2 is covered with a magnetic material through a non-magnetic material.

As illustrated in FIG. 3A, the soft magnetic material 8 formed on the periphery becomes a return path “a” of a leakage magnetic field generated from the memory layer 2, and thus it is possible to reduce the leakage magnetic field.

For the non-magnetic material 7, for example, SiO₂, Al₂O₃, Si₃N₄, or the like, which has high insulation property, is effective. The non-magnetic material 7 is desirable to be a material having an insulation property.

The soft magnetic material 8 is a magnetic material, but has a sufficiently weaker coercive force than a normal magnetic material. Accordingly, the material of the soft magnetic material 8 ought to have a sufficiently weaker coercive force than that of the memory layer 2, and thus NiFe, FeCoB, CoFe, or the like is suitable. Also, the materials are not limited to these, and it is possible to use the other materials that meet the above-described conditions.

In the case of covering the periphery of the memory element 10 with the soft magnetic material 8 through the non-magnetic material 7, it is possible to reduce the leakage magnetic field in the same manner as in the case of covering only the periphery of the memory layer 2. In this case, it becomes easy to manufacture the memory element 10 compared with the case of covering only the periphery of the memory layer 2, and thus is superior in manufacturing.

As illustrated in FIG. 3B, a vertical sectional shape of the memory element 10 according to the embodiment in the lamination direction is substantially a circle. This is the most efficient shape when the memory elements 10 are filled to constitute a memory device, because it is possible to fill the memory elements 10 at a high density by forming the memory element 10 into this shape.

That the vertical sectional shape of the memory element 10 according to the embodiment in the lamination direction is substantially a circle means that the memory element 10 is formed into a cylinder, a truncated cone in shape, or the other shapes like these.

Also, the memory element 10 is suitable to be formed into the above-described shapes. However, the shape is not limited to this, and may be a rectangular column, or the like.

The other examples of a specific configuration of the memory element 10 according to the present embodiment are illustrated in FIG. 4A to FIG. 4D. In each of the figures, the foundation layer 11 is omitted from the memory element 1.

FIG. 4A is an example in which the periphery of the memory element 1 is covered with the non-magnetic material 7, further the outside thereof is covered with the soft magnetic material 8, and the upper section of the protection layer 9 is covered with the soft magnetic material 8. The upper part of the soft magnetic material 8 is directly connected to the protection layer 9, and thus is allowed to be used as an electrode. Since the upper part of the protection layer 9 is sealed with the soft magnetic material 8, it is easy to manufacture.

FIG. 4B is an example in which the periphery of the memory element 1 is covered with the non-magnetic material 7, further the outside thereof is covered with the soft magnetic material 8, and the peripheral part of the upper part of the protection layer 9 is covered with the soft magnetic material 8.

FIG. 4C is an example in which only the periphery of the memory layer 2 of the memory element 1 is covered with the non-magnetic material 7 and the soft magnetic material 8.

FIG. 4D is an example in which the sizes of the memory layer 2 and the laminating structure lower than the memory layer 2 are different, and the periphery of the memory layer 2 is covered with the non-magnetic material 7 and the soft magnetic material 8. In this case, the intermediate layer 3 is insulated, and thus the non-magnetic material 7 may not be an insulating material.

As described above, it is thought that there are various ways to dispose the non-magnetic material 7 and the soft magnetic material 8. However, the present disclosure is not limited to these modes. It is thought that there are various modes without departing from the spirit and scope of the basic modes illustrated in FIGS. 3A and 3B.

In any case of the above-described configurations, in the same manner as in the case in FIGS. 3A and 3B, the soft magnetic material 8 formed on the periphery becomes the return path “a” of the leakage magnetic field generated from the memory layer 2. Thus, it is possible to make the leakage magnetic field small. Accordingly, it is necessary that at least the periphery of the memory layer 2 is covered with a magnetic material through a non-magnetic material.

4. Method of Manufacturing Memory Element According to an Embodiment

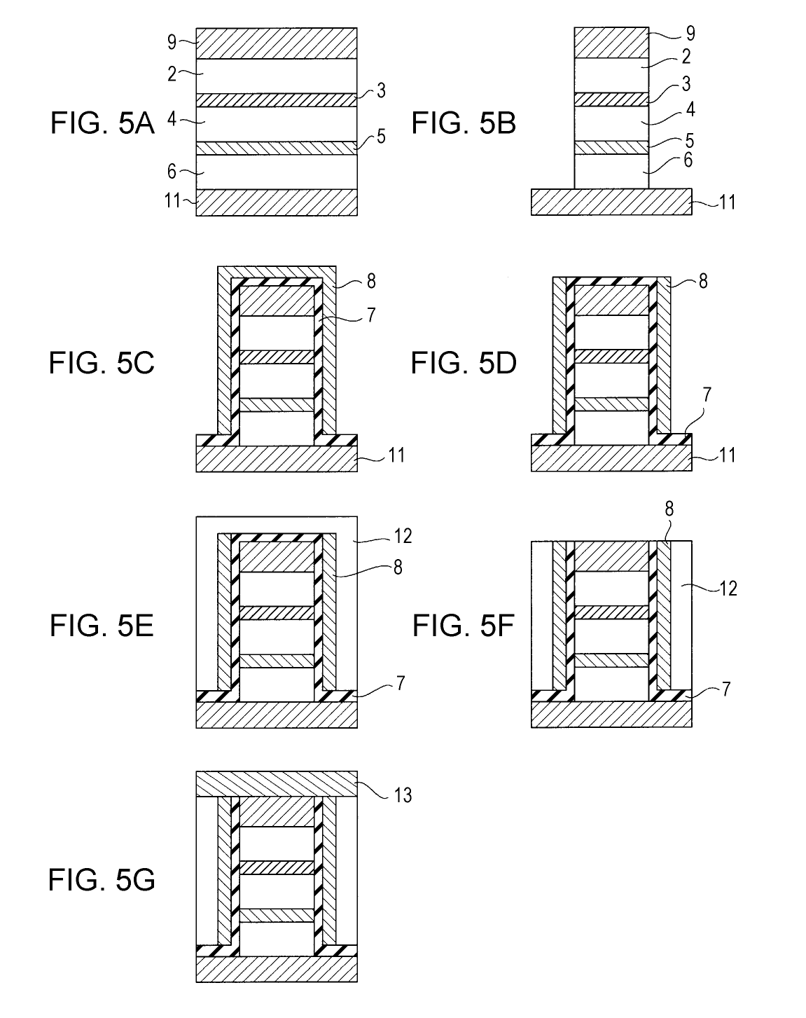

In the following, a description will be given of a method of manufacturing a memory element according to the embodiment with reference to FIGS. 5A to 5G.

First, as illustrated in FIG. 5A, individual layers, namely, a foundation layer 11, a magnetic coupling layer 6, a bonding layer 5, a magnetization-fixed layer 4, an intermediate layer 3, a memory layer 2, and a protection layer 9 are laminated on a substrate.

Next, as illustrated in FIG. 5B, the laminated layers as illustrated in FIG. 5A are entirely formed into a cylindrical shape by shaving off the layers other than the foundation layer 11 by a method, such as photo lithography, or the like.

Next, as illustrated in FIG. 5C, a non-magnetic material 7 and a soft magnetic material 8 are formed on the periphery of the laminated structure part other than the foundation layer 11 in order to cover the overall side surface.

Next, as illustrated in FIG. 5D, etching is applied on the upper surface by selective anisotropic etching to remove the upper part of the soft magnetic material 8, and only the soft magnetic material 8 formed on the peripheral part of the element is remained. The upper part is in a state in which the non-magnetic material 7 remained.

Next, as illustrated in FIG. 5E, a filling material 12 that fills the space of the element is formed on the periphery of the element. Next, as illustrated in FIG. 5F, the upper surface of the element is ground to expose the upper part of the protection layer 9 (electrode). Lastly, as illustrated in FIG. 5G, a wiring line 13 is formed on the electrode exposed in FIG. 5F.

It is possible to manufacture the memory element 10 according to the present embodiment by the method described above.

In the memory element 10 according to the present embodiment, formed as described above, the soft magnetic material 8 formed on the periphery becomes the return path “a” of the leakage magnetic field generated from the memory layer 2, and the leakage magnetic field becomes small. Accordingly, even if the memory elements 10 are filled at a high density, the interaction between the memory elements 10 is reduced. Thus, it is possible to produce the memory elements 10 having a stable retention characteristic and a recording characteristic.

5. Experiment

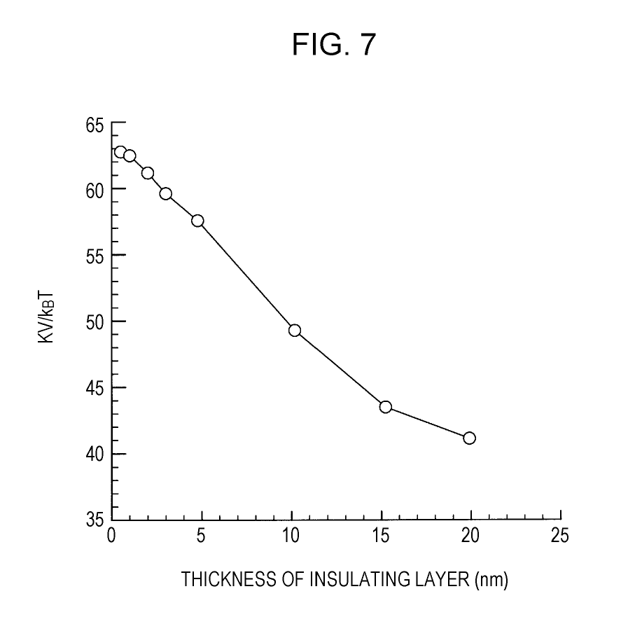

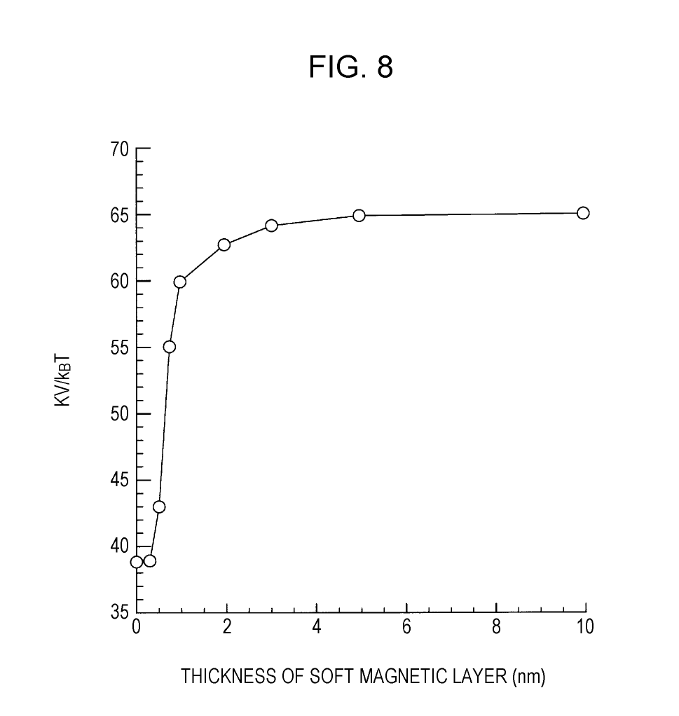

In the following, a description will be given of an experiment result on the stability of information recording of the memory element 10 according to the present embodiment with reference to FIG. 7 and FIG. 8.

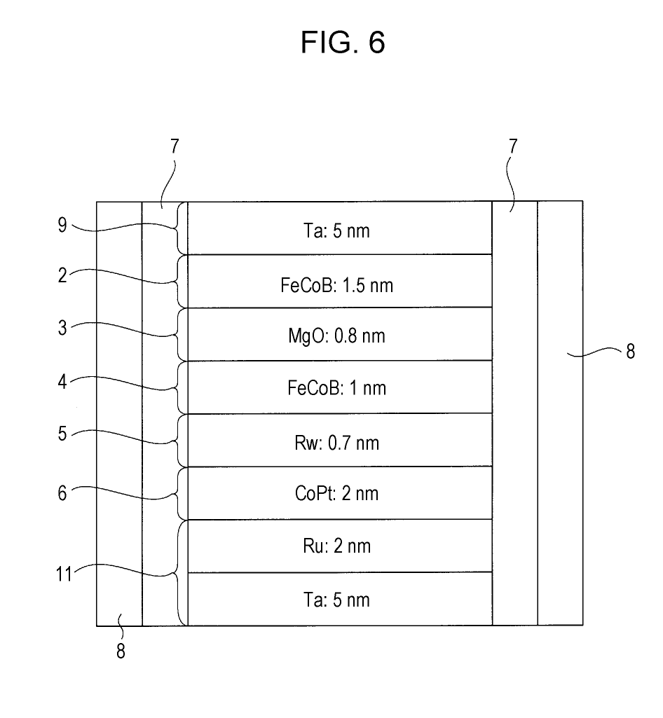

The experiment sample is illustrated in FIG. 6.

As illustrated in FIG. 6, 5-nm Ta, and 2-nm Ru films were formed as the foundation layer 11,

A 2-nm CoPt film was formed as the magnetic coupling layer 6,

A 0.7-nm Ru film was formed as the bonding layer 5,

A 1-nm FeCoB film was formed as the magnetization-fixed layer 4,

A 0.8-nm MgO film was formed as the intermediate layer 3 (tunnel barrier layer),

A 1.5-nm FeCoB film was formed as the memory layer 2, and a 5-nm Ta film was formed as the protection layer 9.

The element was formed into a cylinder having a diameter of 40 nm. The recording stability (thermal stability) index KV/k_{B}T of a single memory element is 39. The recording stability index was obtained from pulse width dependence of the recording current.

As an example of the memory element 10 according to the present disclosure, the non-magnetic material 7 made of Al₂O₃ was formed on the above-described memory element, and then the soft magnetic layer 8 made of FeCo alloy was formed thereon.

FIG. 7 illustrates a change in the recording stability index KV/k_{B}T in accordance with thickness of the insulating layer when the thickness of the non-magnetic material 7 (the insulating layer) was changed at the time the soft magnetic layer thickness is 1 nm. As the thickness of the non-magnetic material 7 (the insulating layer) is increased, KV/k_{B}T becomes low, and the recording stability decreases. The thinner the non-magnetic material 7 (the insulating layer), the recording stability is better, and thus it is desirable to be 5 nm or less. However, if the insulating layer is too thin, the layer lacks insulation. Accordingly, it is desirable to have a certain thickness of 0.5 nm or more.

FIG. 8 illustrates a change in the recording stability index KV/k_{B}T when the thickness of the soft magnetic layer 8 was changed at the time the thickness of the non-magnetic material 7 (the insulating layer) was 2 nm. As the thickness of the soft magnetic layer 8 is increased, KV/k_{B}T increases. However, KV/k_{B}T tends to be saturated at about 2 nm. It is desirable to be 5 nm or less in consideration of productivity and an increase in the element size. Also, if it is too thin, the effect of the soft magnetic layer 8 is lost, and thus it is desirable to have a thickness of 0.5 nm or more.

The memory element 10 according to the present embodiment has the following advantages.

By disposing the soft magnetic material 8 at least on the periphery of the memory layer 2 through the non-magnetic material 7 on the periphery of the memory element 1 having vertical magnetization, it is possible for the soft magnetic material 8 in the periphery of the element to reduce a leakage magnetic field generated by the element by itself, and to weaken the magnetic field from the outside at the same time. Accordingly, in a high-density memory device in which the elements are filled at high density, it is possible to reduce magnetic interference between elements, and to achieve a nonvolatile memory having stable operation and a favorable retention characteristic.

Also, all of the memory elements that are filled are not necessary to be the memory elements 10 according to the present embodiment, and a part of the memory elements may be the memory elements 10. If the memory elements 10 are partially provided, a leakage magnetic field is suppressed on the whole, and thus it is possible to achieve stable operation and a favorable retention characteristic.

In this regard, the advantages described in this specification are only examples, and not limited, and thus the other advantages may also be obtained.

In this regard, it is possible to configure the present technique as follows.

(1) A memory element having a layer structure, the layer structure including:

a memory layer whose magnetization direction is changed in accordance with information;

a magnetization-fixed layer having magnetization perpendicular to a film surface to be a basis of the information stored in the memory layer; and

an intermediate layer made of a non-magnetic material, disposed between the memory layer and the magnetization-fixed layer,

wherein at least a periphery of the memory layer is covered with a magnetic material through a non-magnetic material among the layer structure.

(2) The memory element according to (1),

wherein the non-magnetic material is an insulating material.

(3) The memory element according to (1) or (2),

wherein the non-magnetic material has a thickness of 0.5 nm to 5 nm, and the magnetic material has a thickness of 0.5 nm to 5 nm.

(4) The memory element according to any one of (1) to (3), further including

a magnetic coupling layer being adjacent to the magnetization-fixed layer, and disposed on an opposite side of the intermediate layer.

(5) The memory element according to any one of (1) to (4),

wherein a vertical sectional shape of the layer structure in a lamination direction is substantially a circle.

It should be understood by those skilled in the art that various modifications, combinations, sub-combinations and alterations may occur depending on design requirements and other factors insofar as they are within the scope of the appended claims or the equivalents thereof.

What is claimed is:

1. A memory element having a layer structure, the layer structure comprising:
a memory layer whose magnetization direction is changed in accordance with information;
a magnetization-fixed layer having magnetization perpendicular to a film surface to be a basis of the information stored in the memory layer; and
an intermediate layer made of a non-magnetic material, disposed between the memory layer and the magnetization-fixed layer,
wherein at least a periphery of the memory layer is covered with a magnetic material through a non-magnetic material among the layer structure.

2. The memory element according to claim 1,
wherein the non-magnetic material is an insulating material.

3. The memory element according to claim 1,
wherein the non-magnetic material has a thickness of 0.5 nm to 5 nm, and the magnetic material has a thickness of 0.5 nm to 5 nm.

4. The memory element according to claim 1, further comprising
a magnetic coupling layer being adjacent to the magnetization-fixed layer, and disposed on an opposite side of the intermediate layer.

5. The memory element according to claim 1,
wherein a vertical sectional shape of the layer structure in a lamination direction is substantially a circle.

6. A method of manufacturing a memory element having a layer structure including a memory layer whose magnetization direction is changed in accordance with information, a magnetization-fixed layer having magnetization perpendicular to a film surface to be a basis of the information stored in the memory layer, and an intermediate layer made of non-magnetic material, disposed between the memory layer and the magnetization-fixed layer, the method comprising:
laminating a foundation layer;
laminating the memory layer, the magnetization-fixed layer, and the intermediate layer;
laminating a protection layer; and
covering at least a periphery of the memory layer with a magnetic material through a non-magnetic material among the layer structure produced by each of the laminatings.

7. The method of manufacturing a memory element, according to claim 6, further comprising:
after laminating the foundation layer, the magnetization-fixed layer, the intermediate layer, the memory layer, and the protection layer, and covering at least the periphery of the memory layer with a magnetic material through a non-magnetic material among the laminated layer structure,
filling with a filling material; and
exposing an electrode portion from an upper part of the protection layer,
wherein the covering with the magnetic material uses an anisotropic etching method having selectivity.

8. A memory device including a memory element holding information by a magnetization state of a magnetic material, and two kinds of wiring lines crossing with each other, all of or a part of the memory element having a layer structure, the layer structure comprising:
a memory layer whose magnetization direction is changed in accordance with the information;
a magnetization-fixed layer having magnetization perpendicular to a film surface to be a basis of the information stored in the memory layer; and
an intermediate layer made of a non-magnetic material, disposed between the memory layer and the magnetization-fixed layer,
wherein at least a periphery of the memory layer is covered with a magnetic material through a non-magnetic material among the layer structure,
the magnetization direction of the magnetic layer is changed by applying a current in a lamination direction of the layer structure so that the information is recorded on the memory layer, and
the current flows through the memory element in the lamination direction through the two kinds of wiring lines.
